(19) United States
(12) Patent Application Publication
(10) Pub. No.: US 2025/0331161 A1
(43) Pub. Date: Oct. 23, 2025

(54) SEMICONDUCTOR DEVICE AND MANUFACTURING METHOD THEREOF

(71) Applicant: Yangtze Memory Technologies Co., Ltd., Wuhan (CN)

(72) Inventors: Zongliang HUO, Wuhan (CN); Wei XU, Wuhan (CN); Wenbin ZHOU, Wuhan (CN); Jingyu ZHAI, Wuhan (CN); Bin YUAN, Wuhan (CN)

(21) Appl. No.: 19/176,530

(22) Filed: Apr. 11, 2025

(30) Foreign Application Priority Data
Apr. 17, 2024 (CN) 202410468429.7

(51) Int. Cl. H10B 12/00

(52) U.S. Cl. CPC H10B 12/315; H10B 12/05

(57) ABSTRACT

The examples of the present disclosure provide a semiconductor device and a manufacturing method. One example method includes: forming a plurality of conductive structures; forming a plurality of semiconductor bodies, wherein the semiconductor bodies are located on one side of the conductive structures along a first direction and are connected to the conductive structures; forming a first dielectric layer, wherein the first dielectric layer is located between the plurality of conductive structures; forming a second dielectric layer, wherein the second dielectric layer is located between the plurality of semiconductor bodies; and forming a third dielectric layer, wherein the third dielectric layer is located between the first dielectric layer and the second dielectric layer.

### CROSS-REFERENCE TO RELATED APPLICATIONS

This application claims priority to Chinese Patent Application No. 202410468429.7, filed on Apr. 17, 2024, which is hereby incorporated by reference in its entirety.

### TECHNICAL FIELD

The present disclosure relates to the field of semiconductor technologies, and in particular, to a semiconductor device and a manufacturing method thereof.

### BACKGROUND

A semiconductor device, such as a dynamic random access memory (DRAM), is one of the most important access components in an electronic system, and usually uses a transistor and a capacitor to form a 1T1C structure as a memory cell. Such 1T1C architecture enables dynamic random access memory to have higher integration and lower cost, the 1T1C architecture has an irreplaceable position in computer access devices. With the rapid development of semiconductor technology, dynamic random access memory is rapidly developing towards high density and high quality.

### SUMMARY

According to an aspect of the present disclosure, a semiconductor device is provided, comprising: a plurality of conductive structures; a plurality of semiconductor bodies located on a side of the conductive structures in a first direction and connected to the conductive structures; a first dielectric layer located between the plurality of conductive structures; a second dielectric layer located between the plurality of semiconductor bodies; and a third dielectric layer located between the first dielectric layer and the second dielectric layer.

In some examples, a size of a cross section of the conductive structure perpendicular to the first direction is greater than a size of a cross section of the semiconductor body perpendicular to the first direction.

In some examples, the conductive structure and the semiconductor body form a step structure at a joint of the conductive structure and the semiconductor body, and the step structure comprises a side surface extending along the first direction and a step surface extending along a second direction.

In some examples, sizes of the step structure along the second direction are the same in the first direction, and sizes of the step structure along the first direction are the same in the second direction.

In some examples, the conductive structure comprises at least a metal semiconductor compound layer.

In some examples, a metal element in the metal compound layer comprises nickel, cobalt, or titanium.

In some examples, the conductive structure further comprises a semiconductor layer in contact with the semiconductor body and located on a side of the metal semiconductor compound layer close to the semiconductor body.

In some examples, the semiconductor layer comprises a monocrystalline material or a polycrystalline material.

In some examples, the conductive structure further comprises a metal layer located on a side of the metal semiconductor compound layer away from the semiconductor layer.

In some examples, etching selectivity ratios of the third dielectric layer and the first dielectric layer are different.

In some examples, the first dielectric layer comprises an oxide, and the third dielectric layer comprises a nitride.

In some examples, the third dielectric layer comprises a first sub-dielectric layer and a second sub-dielectric layer; the first sub-dielectric layer extends along a second direction and covers the second dielectric layer, the second sub-dielectric layer extends along a first direction and covers a portion of a side surface of the semiconductor body; and the second direction is perpendicular to the first direction.

In some examples, one of two ends of the semiconductor body opposite to each other along the first direction extends into the conductive structure; and a surface of the semiconductor body close to the conductive structure is higher than a surface of the second sub-dielectric layer close to the conductive structure.

In some examples, a sum of sizes of the second sub-dielectric layer and the semiconductor body in the second direction is the same as a size of the conductive structure in the second direction.

In some examples, the plurality of semiconductor bodies are disposed in an array; the semiconductor device further comprises: a plurality of memory structures, wherein each of the memory structures is located on one of two sides of the conductive structure along the first direction, which is away from the semiconductor body, and is connected to the conductive structure; a plurality of word lines, wherein the word line is coupled to at least one side surface of each semiconductor body of a row of the semiconductor bodies; and a plurality of bit lines, wherein the bit line is coupled to one of two surfaces of each semiconductor body of a column of the semiconductor bodies opposite to each other along the first direction, which is away from the conductive structure.

In some examples, the word line is located on one side surface of the semiconductor body; or the word line is located on two side surfaces of the semiconductor body opposite to each other; or the word line surrounds a side surface of the semiconductor body.

In some examples, two adjacent ones of the semiconductor bodies form a semiconductor body group, and the two semiconductor bodies in one semiconductor body group are separated by a first isolation structure; two adjacent semiconductor body groups are separated by a second isolation structure; and the two word of the lines are respectively located on one of two side surfaces of a respective semiconductor body in the semiconductor body group away from the first isolation structure.

According to another aspect of the present disclosure, a manufacturing method of a semiconductor device is provided, comprising: forming a plurality of conductive structures; forming a plurality of semiconductor bodies, wherein the semiconductor bodies are located on a side of the conductive structures along a first direction and are connected to the conductive structures; forming a first dielectric layer, wherein the first dielectric layer is located between the plurality of conductive structures; forming a second dielectric layer, wherein the second dielectric layer is located between the plurality of semiconductor bodies; and forming a third dielectric layer, wherein the third dielectric layer is located between the first dielectric layer and the second dielectric layer.

In some examples, forming the semiconductor body and the conductive structure comprises: forming a plurality of initial semiconductor bodies extending along the first direction, wherein the plurality of initial semiconductor bodies are separated by an initial dielectric layer; removing a portion of the initial dielectric layer along the first direction to expose a portion of the initial semiconductor body, wherein the remaining of the initial dielectric layer forms the second dielectric layer; forming liner layers covering an exposed side surface of the initial semiconductor body; filling a first dielectric layer between the liner layers; removing a portion of the initial semiconductor body, wherein the remaining of the initial semiconductor body forms the semiconductor body; removing a portion of the liner layer covering a side surface of the first dielectric layer to form a plurality of first trenches, wherein the remaining of the liner layer forms a third dielectric layer; and forming the conductive structure in the first trench.

In some examples, a surface of the remaining of the initial semiconductor body is higher than a surface of the third dielectric layer close to the first dielectric layer.

In some examples, etching selectivity ratios of the liner layer and the first dielectric layer are different.

In some examples, forming the conductive structure in the first trench comprises: forming an initial semiconductor layer in the first trench; and performing a metallization process on the initial semiconductor layer to form a metal semiconductor compound layer.

In some examples, the forming the initial semiconductor layer in the first trench comprises: forming the initial semiconductor layer in the first trench by a deposition process, wherein the initial semiconductor layer comprises a polycrystalline material.

In some examples, the forming the initial semiconductor layer in the first trench comprises: forming the initial semiconductor layer in the first trench by an epitaxial process, wherein the initial semiconductor layer comprises a monocrystalline material.

In some examples, the method further comprises: forming a metal layer on the metal semiconductor compound layer.

In some examples, the method further comprises: forming a memory structure on one of two sides of the conductive structure along the first direction, which is away from the semiconductor body; forming a word line on at least one side of the semiconductor body; and forming a bit line on one of two surfaces of the semiconductor body opposite to each other along the first direction, which is away from the conductive structure.

The examples of the present disclosure provide a semiconductor device and a manufacturing method thereof; wherein the manufacturing method of the semiconductor device comprises: forming a plurality of conductive structures; forming a plurality of semiconductor bodies, wherein the semiconductor bodies are located on one side of the conductive structures along a first direction and are connected to the conductive structures; forming a first dielectric layer, wherein the first dielectric layer is located between the plurality of conductive structures; forming a second dielectric layer, wherein the second dielectric layer is located between the plurality of semiconductor bodies; and forming a third dielectric layer, wherein the third dielectric layer is located between the first dielectric layer and the second dielectric layer. A conductive structure is formed after thickening and metallization using a portion of an initial semiconductor body for forming a semiconductor body, while a semiconductor body is formed using another portion of the initial semiconductor. Because the initial semiconductor body is formed at one time from bottom to top, and the conductive structure and the semiconductor body share the same initial semiconductor body, the conductive structure and the semiconductor body can be directly self-aligned, while the initial semiconductor body can be thickened by the liner layer (corresponding to the third dielectric layer) to obtain a conductive structure with a larger size, thereby improving the connection window between the conductive structure and the memory structure, and also achieving the effect of reducing the contact resistance.

Meanwhile, by thickening the initial semiconductor body by the liner layer, the liner layer can be conformally formed on the surface of the initial semiconductor body, and the process controllability is better; in addition, thickening the initial semiconductor body by the liner layer does not need to provide an additional mask layer, so that the manufacturing cost is reduced.

### BRIEF DESCRIPTION OF DRAWINGS

FIG. 1 is a first schematic structural diagram of a dynamic random access memory according to an example of the present disclosure;

FIG. 2a to FIG. 2d are schematic structural diagrams of a conductive structure in a manufacturing process according to an example of the present disclosure;

FIG. 3 is a schematic flowchart of a manufacturing method of a semiconductor device according to an example of the present disclosure;

FIG. 4a to FIG. 4d are schematic cross-sectional views of a process of forming an initial semiconductor body according to an example of the present disclosure;

FIG. 5a to FIG. 5d are first schematic cross-sectional views of a process of forming a conductive structure and a semiconductor body according to an example of the present disclosure;

FIG. 6a to FIG. 6c are first schematic cross-sectional views of different proportions of a metal semiconductor compound layer in a semiconductor material in several metallization processes according to some examples of the present disclosure;

FIG. 7a to FIG. 7e are second schematic cross-sectional views of a process of forming a conductive structure and a semiconductor body according to an example of the present disclosure;

FIG. 8a to FIG. 8d are third schematic cross-sectional views of a process of forming a conductive structure and a semiconductor body according to an example of the present disclosure;

FIG. 9a to FIG. 9e are fourth schematic cross-sectional views of a process of forming a conductive structure and a semiconductor body according to an example of the present disclosure;

FIG. 10a to FIG. 10i are fifth schematic cross-sectional views of a process of forming a conductive structure and a semiconductor body according to an example of the present disclosure;

FIG. 11a to FIG. 11c are sixth schematic cross-sectional views of a process of forming a conductive structure and a semiconductor body according to an example of the present disclosure;

FIG. 12a to FIG. 12d are second schematic cross-sectional views of different proportions of a metal semiconductor compound layer in a semiconductor material in several metallization processes according to some examples of the present disclosure;

FIG. 13 is a second schematic structural diagram of a dynamic random access memory according to an example of the present disclosure;

FIG. 14 is a third schematic structural diagram of a dynamic random access memory according to an example of the present disclosure.

In the above figures, which are not necessarily drawn to scale, like reference numerals may describe similar components in different views. Like reference numbers with different letter suffixes may represent different examples of similar components. The drawings generally illustrate various examples discussed herein by way of example and not limitation.

### DETAILED DESCRIPTION

Exemplary implementations disclosed in the present disclosure will be described in more detail below with reference to the accompanying drawings. Although exemplary implementations of the present disclosure are shown in the accompanying drawings, it is to be understood that the present disclosure may be implemented in various forms and should not be limited by the specific examples set forth herein. Rather, these examples are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual example are described herein, and well-known functions and structures are not described in detail.

In the drawings, the dimensions of layers, regions, elements, and their relative sizes may be exaggerated for clarity. Like reference numbers refer to like elements throughout.

It should be understood that spatial relation terms such as “beneath,” “below,” “lower,” “under”, “above,” “upper,” etc., may be used herein for ease of description to describe the relationship between one element or feature and other elements or features shown in the figures. It should be appreciated that in addition to the orientations shown in the figures, the spatial relation term intent to also comprise different orientations of the devices in use and operation. For example, if the devices in the figures are flipped, then described as “below” or “under” or “beneath” other elements or features will be oriented “on” other elements or features. Thus, the exemplary terms “below” and “under” may comprise both upper and lower orientations. The devices may be additionally oriented (rotated 90 degrees or other orientations) and the spatial description terminology used herein is interpreted accordingly.

A term used herein is for the purpose of describing a particular example only and is not to be considered as limitation of the present disclosure. As used herein, the singular forms “a”, “an” and “said/the” are intended to comprise the plural forms as well, unless the context clearly dictates otherwise. It should also be understood that the terms “consist of” and/or “comprise”, when used in this description, identify the presence of stated features, integers, steps, operations, elements and/or parts, but do not exclude the presence or addition of one or more other features, integers, steps, operations, elements, parts and/or groups. As used herein, the term “and/or” comprises any and all combinations of the associated listed items.

For a more detailed understanding of the features and technical contents of the examples of the present disclosure, the implementations of the examples of the present disclosure are described in detail below with reference to the accompanying drawings, and the accompanying drawings are for illustrative purposes only and are not intended to limit the examples of the present disclosure.

The semiconductor device involved in the examples of the present disclosure is at least a portion of structure that will be used in subsequent processes to form the final device. Herein, the final device may comprise a memory, which includes, but is not limited to, a dynamic random access memory, and the following takes the dynamic random access memory as an example for illustration. However, it should be noted that, description with regard to the dynamic random access memory in the examples below is only used to illustrate the present disclosure, and is not intended to limit the scope of the present disclosure.

The semiconductor device involved in the examples of the present disclosure is at least a portion of structure that will be used in subsequent processes to form the final device. Herein, the final device may comprise a memory, which includes, but is not limited to, a dynamic random access memory, and the following takes the dynamic random access memory as an example for illustration. However, it should be noted that, description with regard to the dynamic random access memory in the examples below is only used to illustrate the present disclosure, and is not intended to limit the scope of the present disclosure.

With the development of dynamic random access memory technology, the size of the memory cell is smaller and smaller, and the array architecture of the memory cell is from 8F² to 6F² to 4F²; in addition, based on the requirements for dynamic random access memory on ion and leakage current, the architecture of the memory develops from a planar array transistor to a recess gate array transistor, and from the recess gate array transistor to the buried channel array transistor, and then from the buried channel array transistor to the vertical channel array transistor.

In some examples of the present disclosure, whether the transistor is the planar transistor or the buried transistor, the dynamic random access memory is composed of a plurality of memory cells, and each of the memory cells is composed of a transistor and a capacitor controlled by the transistor, that is, the dynamic random access memory comprises an architecture of 1 transistor (T) and 1 capacitance (C) (1T1C); its main function principle is to use the amount of the charges stored in the capacitor to represent whether one binary bit is 1 or 0.

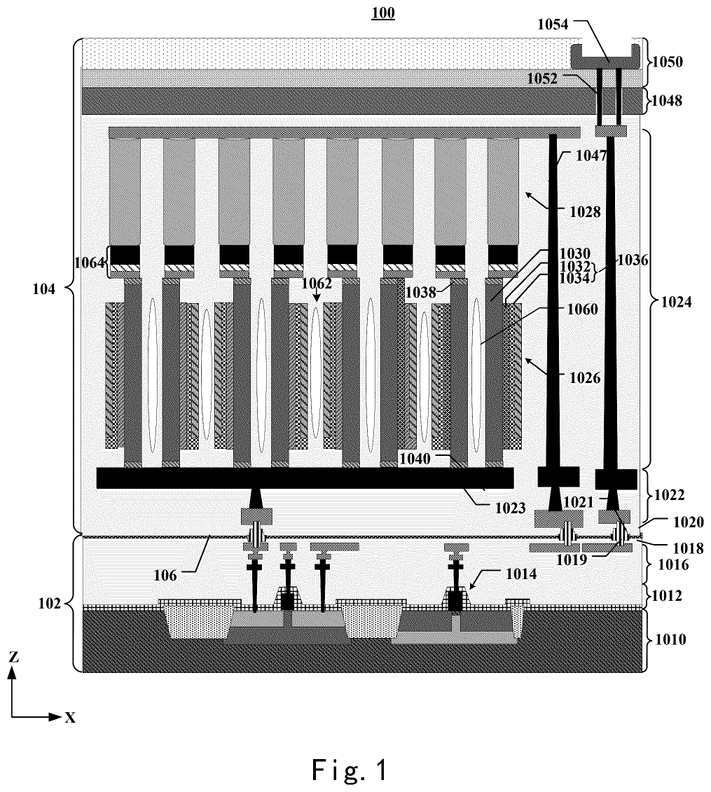

One of the architectures of the dynamic random access memory is described in detail below with reference to FIG. 1. Before describing the semiconductor device illustrated in FIG. 1, various directions that may be used in the following description are firstly defined. The extension direction of the semiconductor body is defined as the first direction (i.e., the Z direction). The intersecting second direction (i.e., the X direction) and the third direction (i.e., the Y direction) are defined in a plane perpendicular to the Z direction. In some examples, the X direction, the Y direction, and the Z direction may be perpendicular to each other.

FIG. 1 shows a cross-sectional view of a three-dimensional (3D) dynamic random access memory 100 comprising vertical transistors according to an example of the present disclosure. As shown in FIG. 1, the dynamic random access memory 100 comprises a first device 102 and a second device 104 stacked on the first device 102 along the Z-axis direction, and the first device 102 and the second device 104 are connected through a bonding interface 106; the first device 102 and the second device 104 may be connected in a hybrid bonding manner, etc. In some examples, the second device 104 may be bonded on top of the first device 102 in a face-to-face manner at the bonding interface 106. The first device 102 may comprise a first substrate 1010, a peripheral circuit 1012 located on a side of the first substrate 1010, and a first interconnection layer 1016 located on a side of the peripheral circuit 1012 away from the first substrate 1010, wherein the first interconnection layer 1016 is configured to transmit an electrical signal of the peripheral circuit 1012. The peripheral circuit 1012 may comprise a plurality of transistors 1014. In some examples, trench isolation (e.g., shallow trench isolation (STI)) and doped regions (e.g., well, source, and drain of transistor 1014) may also be formed on or in the first substrate 1010.

The first device 102 may further comprise a first bonding layer 1018 at the bonding interface 106 and located on a side of the first interconnection layer 1016 away from the peripheral circuit 1012. The first bonding layer 1018 may comprise a plurality of first bonding contacts 1019 and a dielectric for electrically isolating the first bonding contacts 1019. The first bonding contact 1019 and the surrounding dielectric in the first bonding layer 1018 may be used for hybrid bonding. Correspondingly, the second device 104 may also comprise a second bonding layer 1020 at the bonding interface 106 and located on a side of the first bonding layer 1018 away from the first interconnection layer 1016. The second bonding layer 1020 may comprise a plurality of second bonding contacts 1021 and a dielectric for electrically isolating the second bonding contacts 1021. The second bonding contact 1021 and the surrounding dielectric in the second bonding layer 1020 may be used for hybrid bonding. Herein, the second bonding contact 1021 is in contact with the first bonding contact 1019 at the bonding interface 106.

In some examples, the peripheral circuitry 1012 may further comprise a word line driver/row decoder coupled to a word line (WL) in the second interconnect layer 1022 through the second bonding contact 1021 in the second bonding layer 1020 and the first bonding contact 1019 in the first bonding layer 1018 and the first interconnect layer 1016. In some other examples, the peripheral circuit 1012 may further comprise a bit line driver/column decoder coupled to the bit line (BL) 1023 in the second interconnect layer 1022 through the second bonding contact 1021 in the second bonding layer 1020 and the first bonding contact 1019 in the first bonding layer 1018 and the first interconnect layer 1016. Herein, the second interconnect layer 1022 comprises a bit line 1023 over the second bonding layer 1020 for transmitting electrical signals. In some other examples, the stacked first device 102 and the second device 104 may not be connected by bonding, but are integrated on the same substrate (there is only the first substrate and not the second substrate), and are directly connected through one or more interconnection layers between the first device 102 and the second device 104. In this case, the first bonding layer 1018 and the first bonding contact 1019 are not present in the first device 102; the second bonding layer 1020 and the second bonding contact 1019 are not present in the second device 104; and the bonding interface 106 between the first device 102 and the second device 104 is not present.

Referring to FIG. 1, the second device 104 further comprises an array of memory cells which may comprise a plurality of memory cells 1024 on the second interconnect layer 1022, a second substrate 1048 on the memory cells 1024, and a third interconnect layer 1050 on the second substrate 1048. The cross section of the dynamic random access memory 100 in FIG. 1 may be taken along the bit line direction (X-axis direction), and one of the bit lines 1023 in the second interconnect layer 1022 extending laterally in the X-axis direction may be coupled to a column of memory cells 1024.

Herein, each memory cell 1024 may comprise a vertical transistor 1026 and a capacitor structure 1028 coupled to the vertical transistor 1026; the vertical transistor 1026 comprises a semiconductor body 1030 extending vertically (in the Z-axis direction), and a gate structure 1036 in contact with one side of the semiconductor body 1030 in the bit line direction (X-axis direction); in some other examples, the gate structure may also fully surround the semiconductor body, semi-surround the semiconductor body, be located on two opposite sides of the semiconductor body, and the like, and details are not described herein again. Herein, the gate structure 1036 comprises a gate electrode 1034 and a gate dielectric 1032 located between the gate electrode 1034 and the semiconductor body 1030 in the bit line direction (X-axis direction). In some examples, the gate dielectric 1032 adjoins one side of the semiconductor body 1030, and the gate electrode 1034 adjoins the gate dielectric 1032.

In some examples, the semiconductor body 1030 has two ends (upper end and lower end) in the vertical direction (Z-axis direction), and one end (such as the lower end in FIG. 1) extends beyond the gate dielectric 1032 and into an interlayer dielectric (ILD) layer in the vertical direction (Z-axis direction), and the other end (such as the upper end in FIG. 1) of the semiconductor body 1030 is flush with the respective ends of the gate dielectric 1032. In some other examples, the two ends (upper end and lower end) of the semiconductor body 1030 extend beyond the gate electrode 1034 and into the ILD layer in the vertical direction (Z-axis direction), respectively. In other words, the semiconductor body 1030 may have a larger vertical dimension (e.g., depth in the Z-axis direction) than that of the gate electrode 1034, and neither the upper end nor the lower end of the semiconductor body 1030 is flush with the respective ends of the gate electrode 1034. As such, a short circuit between the bit line 1023 and the word line/gate electrode 1034 or between the word line/gate electrode 1034 and the capacitor structure 1028 may be avoided.

The vertical transistor 1026 may further comprise a source 1038 and a drain 1040 respectively disposed at two ends (upper end and lower end) of the semiconductor body 1030 in the vertical direction (Z-axis direction) (the positions of the source and the drain may be interchanged, and the upper end is the source 1038 and the lower end is the drain 1040 as an example here and below). In some implementations, source 1038 is coupled to capacitor 1028, and drain 1040 is coupled to bit line 1023.

Since the gate electrode may be part of a word line or extend as a word line in a word line direction, the second device 104 of the dynamic random access memory 100 may also comprise a plurality of word lines each extending in a word line direction (Y-axis direction). Herein, each word line 1034 may be coupled to a row of memory cells 1024.

The vertical transistor 1026 extends vertically through the word line 1034 and is in contact with the word line 1034, and is in contact with the bit line 1023 at the drain 1040 at its lower end. Thus, due to the vertical arrangement of vertical transistors 1026, word line 1034 and bit line 1023 may be disposed in different planes in the vertical direction, which simplifies the routing of word line 1034 and bit line 1023. Herein, the vertical transistors 1026 may be arranged in mirror symmetry to increase the density of the memory cells 1024 in the bit line direction (X-axis direction). Two adjacent vertical transistors 1026 in the bit line direction are mirror symmetric to each other with respect to the trench isolation 1060, that is, the second device 104 may comprise a plurality of trench isolations 1060, each trench isolation 1060 extending in a word line direction (Y-axis direction) parallel to the word line 1034 and being disposed between two adjacent rows of semiconductor bodies 1030 of the vertical transistor 1026. In some implementations, rows of vertical transistors 1026 separated by trench isolation 1060 are mirror symmetric to each other with respect to trench isolation 1060. It should be understood that trench isolation 1060 may comprise air gaps, each disposed laterally between adjacent semiconductor bodies 1030. The second device 104 also comprises a plurality of gate isolation 1062, each gate isolation 1062 extending in a word line direction (Y-axis direction) parallel to the word line 1034 and disposed between two adjacent rows of word lines 1034 of the vertical transistor 1026. It should be understood that the size of the gate isolation 1062 and the word line 1034 in the bit line direction (X-axis direction) and the size of the trench isolation 1060 in the bit line direction (X-axis direction) may be the same or different; when the sizes of both in the bit line direction (X-axis direction) are different, the spacings between the plurality of semiconductor bodies 1030 arranged along the bit line direction (X-axis direction) are different, that is, the plurality of semiconductor bodies 1030 arranged along the bit line direction (X-axis direction) are arranged in a non-uniform manner.

As shown in FIG. 1, the capacitor structure 1028, which may be a vertical capacitance, is over and in contact with the source 1038 of the vertical transistor 1026 (i.e., the upper end of the semiconductor body 1030).

In some implementations, a conductive structure 1064 is formed between the capacitor structure 1028 and the vertical transistor 1026 to reduce contact resistance. As shown in FIG. 1, the conductive structure 1064 may comprise a semiconductor layer, a metal semiconductor compound layer, and a metal layer sequentially stacked from bottom to top.

As shown in FIG. 1, the second device 104 may also comprise a capacitive contact 1047 in contact with the common plate of the vertical transistor 1026 for coupling the second electrode 1046 of the capacitor structure 1028 to the peripheral circuit 1012 or directly coupling to ground. In some implementations, the ILD layer forming the capacitor structure 1028 has the same dielectric material as the two ILD layers into which the semiconductor body 1030 extends, such as silicon oxide. The configuration of the capacitor structure 1028 may comprise any suitable structure and configuration, such as planar capacitors, stacked capacitors, multi-fin capacitors, cylindrical capacitors, trench capacitors, or substrate-plate capacitors.

As shown in FIG. 1, the vertical transistor 1026 extends vertically through the word line 1034 and is in contact with the word line 1034, the vertical transistor 1026 is in contact with bit line 1023 at drain 1040 at its lower end, and the vertical transistor 1026 is in contact with capacitor structure 1028 at source 1038 at its upper end. That is, due to the vertical arrangement of the vertical transistors 1026, the bit line 1023 and the capacitor structure 1028 may be disposed in different planes in the vertical direction and coupled to opposite ends of the vertical transistors 1026 of the memory cells 1024 in the vertical direction. In some implementations, the bit line 1023 and the capacitor structure 1028 are disposed on opposite sides of the vertical transistor 1026 in the vertical direction, which simplifies routing of the bit line 1023 and reduces the coupling capacitance between the bit line 1023 and the capacitor structure 1028 as compared to conventional memory cells in which the bit line and the capacitor structure are disposed on the same side of the planar transistor.

In some examples, the vertical transistor 1026 is vertically disposed between the capacitor structure 1028 and the bonding interface 106. That is, the vertical transistor 1026 may be arranged closer to the peripheral circuitry 1012 and the bonding interface 106 of the first device 102 than the capacitor structure 1028. Because bit line 1023 and capacitor structure 1028 are coupled to opposite ends of vertical transistor 1026, as such bit line 1023 (as part of second interconnect layer 1022) is vertically disposed between vertical transistor 1026 and bonding interface 106 to reduce interconnect routing distance and complexity.

In some examples, the second device 104 further comprises a second substrate 1048 disposed over the memory cell 1024, and a pad-out third interconnect layer 1050 disposed over the memory cell 1024. The pad-out third interconnect layer 1050 may comprise interconnect in one or more ILD layers, e.g., contact pads 1054.

In some examples, the second device 104 further comprises one or more contacts 1052 extending through the portion of the pad-out third interconnect layer 1050 and the second substrate 1048 to couple the pad-out third interconnect layer 1050 to the memory cell 1024 and the second interconnect layer 1022. As such, the peripheral circuit 1012 may be coupled to the memory cell 1024 through the first interconnect layer 1016 and the second interconnect layer 1022 and the second bonding layer 1020 and the first bonding layer 1018, and the peripheral circuit 1012 and the memory cell 1024 may be coupled to the external circuit through the contact 1052 and the pad-out third interconnect layer 1050.

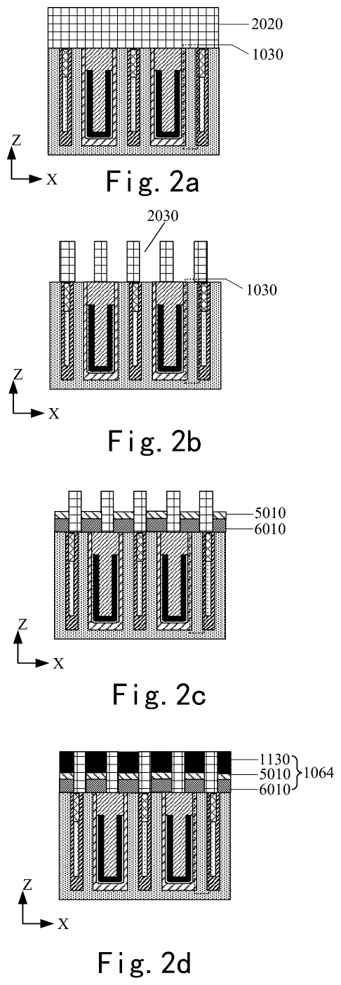

As described above, in order to reduce the contact resistance between the capacitor structure 1028 and the vertical transistor 1026, a conductive structure 1064 is disposed between the capacitor structure 1028 and the vertical transistor 1026. An example of the present disclosure provides a manufacturing method of a conductive structure 1064, referring to FIGS. 2a-2d.

As shown in FIG. 2a, a mask layer 2020 is formed on the semiconductor body 1030 (subsequently used to form the vertical transistor 1026 described above).

As shown in FIG. 2b, a conductive hole 2030 is formed in the mask layer 2020 by using a self-aligned technology to expose a surface of the semiconductor body 1030 close to the mask layer 2020.

As shown in FIG. 2c, a semiconductor material (such as polysilicon) is deposited in the conductive hole 2030, the semiconductor material is doped optionally, and the semiconductor material is etched back (EB) to form the semiconductor layer 6010; then, a metal semiconductor compound layer 5010, such as cobalt silicide (CoSi), is formed on the semiconductor layer.

As shown in FIG. 2d, a metal material is deposited in the conductive hole 2030, and a chemical mechanical polish (CMP) is performed to form a metal layer 1130, such as titanium nitride TiN, tungsten W and the like, on the metal semiconductor compound layer 5010. The semiconductor layer 6010, the metal semiconductor compound layer 5010, and the metal layer 1130 form a conductive structure 1064.

In the above examples, the alignment accuracy between the semiconductor body 1030 and the conductive structure greatly depends on the pattern precision of the mask layer, and the photolithography process requirement corresponding to the mask layer is high, while the depth difference between the semiconductor body and the word line in the Z-axis direction, the technical defect existing in the process of forming the metal silicide layer, and the like, so that the alignment difficulty between the conductive structure 1064 and the semiconductor body 1030 is increased. In addition, there are also issues such as increased production costs for the mask layer.

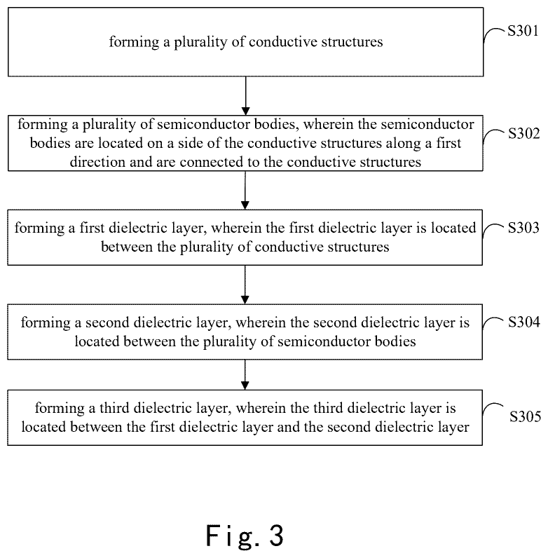

Based on this, to solve one or more of the above issues, an example of the present disclosure further provides a manufacturing method of a semiconductor device. Referring to FIG. 3, FIG. 3 is a schematic flowchart of a manufacturing method of a semiconductor device according to an example of the present disclosure; the method comprises:

Operation S301: forming a plurality of conductive structures;

Operation S302: forming a plurality of semiconductor bodies, wherein the semiconductor bodies are located on a side of the conductive structures along a first direction and are connected to the conductive structures;

Operation S303: forming a first dielectric layer, wherein the first dielectric layer is located between the plurality of conductive structures;

Operation S304: forming a second dielectric layer, wherein the second dielectric layer is located between the plurality of semiconductor bodies;

Operation S305: forming a third dielectric layer, wherein the third dielectric layer is located between the first dielectric layer and the second dielectric layer.

It should be understood that the operations shown in FIG. 3 are not exclusive, and other operations may be performed before, after, or between any operations in the illustrated operations; the sequence of the operations shown in FIG. 3 may be adjusted according to actual needs. It should be noted that the semiconductor device may comprise a conductive structure, a semiconductor body and a memory structure or a plurality of conductive structures, a plurality of semiconductor bodies, and a plurality of memory structures. Herein and the following takes the semiconductor device comprising a plurality of conductive structures, a plurality of semiconductor bodies and a plurality of memory structures as an example.

As described above, there may be a plurality of different relative positions between the gate structure and the semiconductor body in the semiconductor device, and different relative positions correspond to different manufacturing methods. In the examples of the present disclosure, taking an example in which two gate structures corresponding to two adjacent semiconductor bodies are disposed back-to-back (the configuration shown in FIG. 1 is the back-to-back configuration) to illustrate, and based on this, the semiconductor device may comprise a plurality of conductive structures, a plurality of semiconductor bodies, and a plurality of memory structures arranged in an array along the X-axis direction and the Y-axis direction. However, it should be understood that the following methods for forming the semiconductor structure are only used to illustrate the present disclosure, and are not intended to limit the scope of the present disclosure.

There are various methods for forming conductive structures and semiconductor bodies, and several of them are exemplarily illustrated in the examples of the present disclosure. The formation process of a plurality of conductive structures and a plurality of semiconductor bodies will be described in detail below with reference to the accompanying drawings.

In the process of performing operations S301 to S305, the formation process of the conductive structure and the semiconductor body is first described.

In some examples, forming the conductive structure and the semiconductor body comprises:
Forming a plurality of initial semiconductor bodies extending along the first direction, wherein the plurality of initial semiconductor bodies are separated by an initial dielectric layer;
Removing a portion of the initial dielectric layer along the first direction to expose a portion of the initial semiconductor body, wherein the remaining of the initial semiconductor body forms the semiconductor body;
Performing a metallization process on at least portion of the exposed initial semiconductor body to form a metal semiconductor compound layer; and using the exposed initial semiconductor body subjected to the metallization process as the conductive structure.

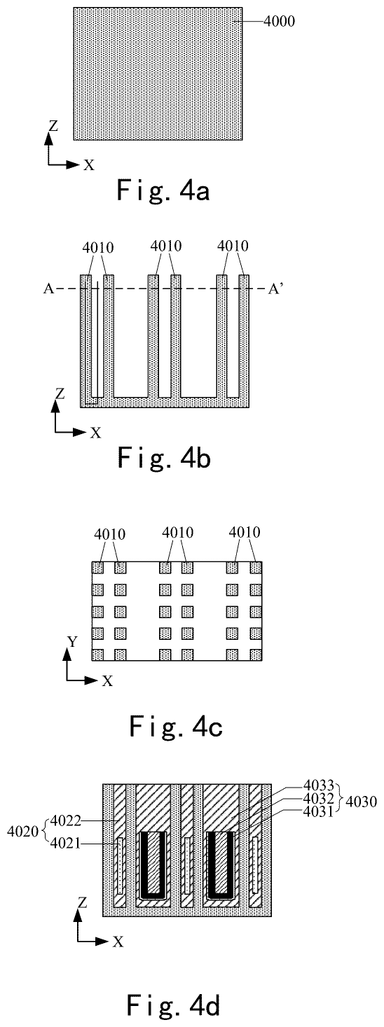

FIG. 4a to FIG. 4d are schematic cross-sectional views of a process of forming an initial semiconductor body according to an example of the present disclosure. It should be noted that FIG. 4c is a schematic cross-sectional view along the AA′ direction in FIG. 4b; and a process of forming the plurality of initial semiconductor bodies is described in detail below with reference to the accompanying drawings.

Referring to FIG. 4a, the substrate 4000 is provided, and the substrate 4000 may comprise a semiconductor material, such as silicon, and more specifically, the substrate 4000 may comprise monocrystalline silicon.

Referring to FIG. 4b and FIG. 4c, a plurality of initial semiconductor bodies 4010 arranged in an array are formed in the substrate 4000. In some examples, the way of forming the initial semiconductor body 4010 may comprise: firstly forming a plurality of trenches extending along the X-axis direction in the substrate 4000, filling the trenches with an insulating material (such as silicon oxide), then forming a plurality of trenches extending along the Y-axis direction in the substrate 4000, wherein the trenches extending along the Y-axis direction are adjusted according to the relative positions between the gate structures and the semiconductor body, and when the two gate structures corresponding to the two adjacent semiconductor bodies shown in FIG. 4b are respectively disposed back to back, the trenches extending in the Y-axis direction comprise alternately disposed trenches with different sizes, and removing the remaining insulating material which is used to fill the trenches previously, that is, forming the initial semiconductor pillar body 4010 arranged in an array.

It should be noted that the cross section of the initial semiconductor body shown in FIG. 4c along the X-axis and the Y-axis is square, the shape is only used as an example, and is not intended to limit the shape of the initial semiconductor body and the semiconductor body subsequently formed by the initial semiconductor body in the cross section, and the shape of the initial semiconductor body and the semiconductor body in the cross section may also comprise a rectangle, a circle, an ellipse, and a similar shape of these shapes.

In some other examples, the manner of forming the initial semiconductor body 4010 may further comprise: first forming a plurality of trenches extending along the Y-axis direction in the substrate 4000, filling the trenches with an insulating material (such as silicon oxide), and then forming a plurality of trenches extending along the X-axis direction in the substrate 4000.

In some examples, trenches along the X-axis direction and/or the Y-direction may be formed by a photolithography process (it may be understood as Lithography-Etch (LE) herein and below). Methods of filling the recesses with insulating materials comprise, but are not limited to, physical vapor deposition (PVD), chemical vapor deposition (CVD), atomic layer deposition (ALD), and the like.

Next, referring to FIG. 4d, a first isolation structure 4020 and a second isolation structure 4030 are respectively formed in the trenches extending along the Y-axis direction according to requirements of a subsequent process of the semiconductor device. It may be understood that the first isolation structure 4020 herein functions similarly to the trench isolation 1060 in FIG. 1, and the second isolation structure 4030 functions similarly to the gate isolation 1062 in FIG. 1.

In some examples, as shown in FIG. 4d, the first isolation structure 4020 may comprise an air gap 4021 and a cap layer 4022, wherein the air gap 4021 may comprise air; and the cap layer 4022 comprises, but is not limited to, silicon oxide. In some other examples, the first isolation structure 4020 may also comprise a conductive material layer and a protective layer (not shown in FIG. 4d), and the conductive material layer may play a better electrostatic shielding effect. However, it should be noted that when the first isolation structure 4020 comprises the conductive material layer, the protection layer needs to surround the conductive material layer to prevent the conductive material layer from contacting the semiconductor pillar. In some examples, the method of forming the first isolation structure 4020 comprises, but is not limited to, PVD, CVD, ALD, or the like.

In some examples, as shown in FIG. 4d, the second isolation structure 4030 may comprise a gate structure 4031, a gate spacer layer 4032 between the gate structures, and an initial dielectric layer 4033 on the gate structure, wherein the gate structure 4031 may comprise a gate electrode and a gate dielectric, and optionally, the gate structure 4031 may further comprise a barrier layer between the gate electrode and the gate dielectric. The gate electrode may comprise, but is not limited to, tungsten, the gate dielectric comprises, but is not limited to, silicon oxide, and the barrier layer comprises, but is not limited to, titanium nitride. The gate spacer layer 4032 and the initial dielectric layer 4033 may be the same or different. For example, both the gate spacer layer 4032 and the initial dielectric layer 4033 are silicon oxide. In some examples, the method for forming the gate structure 4031 in the second isolation structure 4030 comprises, but is not limited to, deposition and etching, or the like; the method for forming the gate spacer layer 4022 in the second isolation structure 4030 comprises, but is not limited to, deposition and etching, or the like; and the method for forming the initial dielectric layer 4033 in the second isolation structure 4030 comprises, but is not limited to, deposition and CMP, or the like.

It should be noted that from FIG. 2a to the cross-sectional views of the following manufacturing process are all intermediate stages of manufacturing, and some of the structural shapes shown in the figures may not be the final product morphology of the semiconductor device, such as the lower ends (close to the ends of the substrates) of the word lines (gate electrodes) shown in the figure are connected together, and the lower ends of the word lines (gate electrodes) in the final product of the semiconductor device are disconnected to form a back-to-back type.

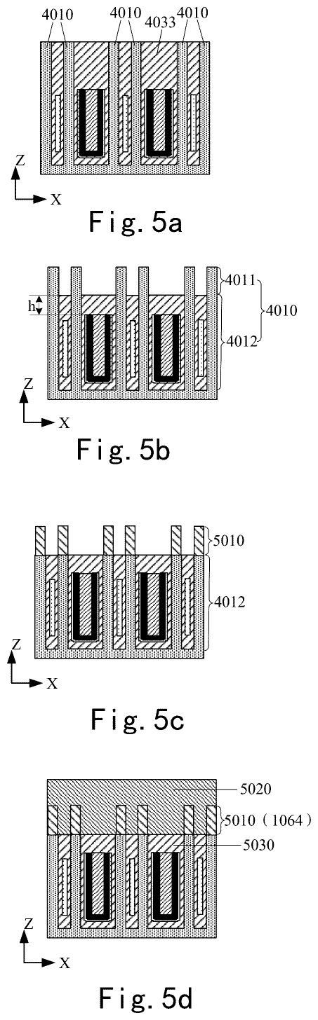

FIG. 5a to FIG. 5d are first schematic cross-sectional views of a process of forming a conductive structure and a semiconductor body according to an example of the present disclosure. In the examples of the present disclosure, the exposed surface of the upper end of the initial semiconductor body is metalized. Specifically:

Referring to FIG. 5a, a plurality of initial semiconductor bodies 4010 extending along the Z-axis direction are formed; the plurality of initial semiconductor bodies 4010 are separated by an initial dielectric layer 4033. For specific formation of the initial semiconductor body 4010 may refer to the examples given in FIG. 4a to FIG. 4d.

Referring to FIG. 5b, a portion of the initial dielectric layer 4033 is removed from the top of the initial dielectric layer along the Z-axis direction to expose a portion of the initial semiconductor body. In this case, the initial semiconductor body 4010 comprises an exposed initial semiconductor body 4011 and an unexposed initial semiconductor body 4012. In some examples, after a portion of the initial dielectric layer is removed, a top surface of the remaining of the initial dielectric layer is higher than a top surface of the gate electrode, that is, there is a height difference h between the remaining of the initial dielectric layer and the gate electrode, so that a portion of the initial semiconductor body corresponding to the height difference may be used to form a drain or a source of the vertical transistor. In some specific examples, the method for removing the portion of the initial dielectric layer 4033 comprises, but is not limited to, dry etching.

Referring to FIG. 5c, metallization process is performed on at least portion of the exposed initial semiconductor body 4011 to form a metal semiconductor compound layer 5010. In some specific examples, the metal elements in the metal semiconductor compound layer 5010 comprise, but are not limited to, nickel, cobalt, titanium, or the like.

In some specific examples, forming the metal semiconductor compound layer 5010 comprises: forming an initial metal layer (not shown in FIG. 5c) covering the exposed surface (including the top surface and each side surface of the exposed initial semiconductor body 4011 in FIG. 5b) of the to-be-metallized structure; and performing an annealing treatment on the to-be-metallized structure with the initial metal layer to form the metal semiconductor compound layer.

It should be noted that, the metallization process is mainly performed in a semiconductor material covering the initial metal layer, and is not performed in a non-semiconductor material, such as an oxide or a nitride, covering the initial metal layer. Based on this, after forming the metal semiconductor compound layer, it is generally necessary to remove the remaining of the initial metal layer covering the non-semiconductor material.

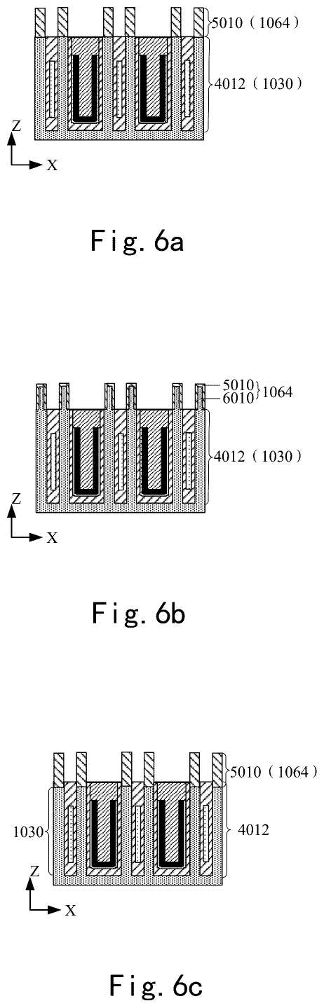

FIG. 6a to FIG. 6c are first schematic cross-sectional views of different proportions of a metal semiconductor compound layer in a semiconductor material in several metallization processes according to some examples of the present disclosure. It should be noted that FIG. 6a to FIG. 6c are several possible metallization cases corresponding to FIG. 5c.

In some specific examples, as shown in FIG. 6a, in the metallization process, the exposed initial semiconductor body 4011 is all metalized. Based on this, the formed conductive structure 1064 is all metal semiconductor compound layers, and the unexposed initial semiconductor body 4012 forms the semiconductor body 1030.

In some specific examples, as shown in FIG. 6b, in the metallization process, the portion of the exposed the initial semiconductor body 4011 is metalized, and the interior of the exposed initial semiconductor body 4011 is still the semiconductor layer 6010. Based on this, the formed conductive structure 1064 comprises a semiconductor layer 6010 and a metal semiconductor compound layer 5010 surrounding the semiconductor layer 6010, and the unexposed initial semiconductor body 4012 forms the semiconductor body 1030. It is understood that since the semiconductor layer 6010 is actually a portion of the exposed initial semiconductor body 4011, the semiconductor layer 6010 is consistent with the entire initial semiconductor body, such as single crystal silicon, while there is no interface between the semiconductor layer 6010 and the unexposed initial semiconductor body 4012.

In some specific examples, as shown in FIG. 6c, in the metallization process, the exposed initial semiconductor body 4011 is all metalized while the metal semiconductor compound layer 5010 extends further into the unexposed initial semiconductor body 4012. It should be noted that in this case, the metal semiconductor compound extending into the unexposed initial semiconductor body 4012 may not necessarily be the regular shape shown in FIG. 6c, for example, the bottom located at the middle is lower than the bottom located at the edge. Based on this, there is a certain overlap between the formed conductive structure 1064 and the unexposed initial semiconductor body 4012. In this case, the formed conductive structure 1064 is all the metal semiconductor compound layers, and the unmetallized portion of the unexposed initial semiconductor body 4012 forms the semiconductor body 1030.

It can be understood that in the foregoing example, the conductive structure 1064 is formed directly using a portion of the initial semiconductor body 4010, while the semiconductor body 1030 is formed by using another portion of the initial semiconductor 4010. Because the initial semiconductor body 4010 is formed once from bottom to top, and the conductive structure 1064 and the semiconductor body 1030 share the same initial semiconductor body 4010, the conductive structure 1064 and the semiconductor body 1030 can be directly self-aligned, and the use of the mask layer is omitted. In this way, the alignment precision between the conductive structure and the semiconductor body in the examples of the present disclosure is high, the difficulty of manufacturing process is reduced, and the mask layer may not be used, so the manufacturing process may be saved, and the manufacturing cost of the semiconductor device may be reduced.

Here, the self-alignment may be understood as the geometric center alignment of the conductive structure 1064 and the semiconductor body 1030; or the side surface of the conductive structure 1064 is aligned with the side surface of the semiconductor body along the Z-axis direction; or the normal projections of the cross section of the conductive structure and the semiconductor body 1030 perpendicular to the first direction overlap. It should be noted that the geometric centers of the conductive structure 1064 and the semiconductor body 1030 have a small deviation due to manufacturing errors or the like, or the small size changes (overall thickened or tapered) of the exposed initial semiconductor body 4011 generated before and after the metallization process are within the scope of the present disclosure.

In some examples, referring to FIG. 5d, after the plurality of conductive structures 1064 are formed, the first dielectric layer 5020 is filled between the plurality of conductive structures 1064, and the top surface of the first dielectric layer 5020 is not lower than the top surface of the conductive structure 1064; the remaining of the initial dielectric layer forms the second dielectric layer 5030; and the first dielectric layer 5020 is the same as or different from the second dielectric layer 5030. In some specific examples, the first dielectric layer 5020 is the same as the second dielectric layer 5030, for example, both materials comprise silicon oxide. In some other specific examples, the first dielectric layer 5020 is different from the second dielectric layer 5030, for example, the first dielectric layer 5020 comprises silicon nitride or silicon boron nitride, and the second dielectric layer 5030 comprises silicon oxide. In some specific examples, the method of filling the first dielectric layer 5020 comprises, but is not limited to, PVD, CVD, or the like.

It should be noted that the selection of the first dielectric layer 5020 mainly considers to form a memory structure in a subsequent process, and specifically, the memory structure comprises a capacitor, and when the capacitor is formed, since the size of the capacitor is longer along the Z-axis direction, multiple supporting layer is generally formed, and the insulating layer filled in the supporting layer is hollowed out, and the insulating layer may comprise silicon oxide. In order to prevent the removing of the insulating layer between the supporting layers by wet etching from affecting the second dielectric layer 5030, the first dielectric layer 5020 needs to be configured with a material with different etching selectivity ratio from the insulating layer, so as to act as a barrier. Therefore, when the first dielectric layer 5020 comprises silicon nitride or silicon nitride boron, the first dielectric layer 5020 may directly act as a barrier, and when the first dielectric layer 5020 comprises silicon oxide, a layer of material with an etching selectivity ratio different from that of the insulating layer needs to be formed on the first dielectric layer 5020 before forming the capacitor.

It should be noted that, in the scenario of the back-to-back gate structure, the arrangement of the plurality of semiconductor bodies along the X-axis is not uniform, after the conductive structure and the semiconductor body are self-aligned, the non-uniform arrangement along the X-axis is also presented, and the memory structure connected to the conductive structure is arranged uniformly along the X-axis. In this case, in order to improve the connection window between the conductive structure and the memory structure, the size of the bottom of the memory structure may be enlarged. In some specific examples, a size of a cross section of one end of the memory structure close to the conductive structure in a direction perpendicular to the Z-axis is greater than a size of a cross section of one end of the memory structure away from the conductive structure in a direction perpendicular to the Z-axis.

In some specific examples, the method further comprises:
Forming a semiconductor thickening layer on the periphery of the exposed initial semiconductor body by an epitaxial process before performing metallization process on at least portion of the exposed initial semiconductor body;
Performing at least metallization process on at least portion of the exposed initial semiconductor body and the semiconductor thickening layer to form the metal semiconductor compound layer; and using the exposed initial semiconductor body and the semiconductor thickening layer subjected to the metallization process as the conductive structure.

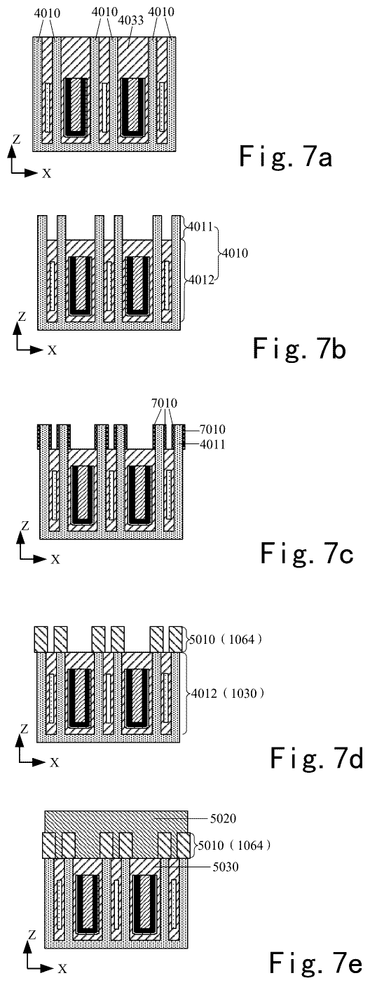

FIG. 7a to FIG. 7e are second schematic cross-sectional views of a process of forming a conductive structure and a semiconductor body according to an example of the present disclosure. In the examples of the present disclosure, the exposed surface of the upper end of the initial semiconductor body is thickened and then metallized. Specifically:

Referring to FIG. 7a, a plurality of initial semiconductor bodies 4010 extending along the Z-axis direction are formed; the plurality of initial semiconductor bodies 4010 are separated by an initial dielectric layer 4033. The specific formation of the initial semiconductor body 4010 may refer to the examples given in FIG. 4a to FIG. 4d.

Referring to FIG. 7b, a portion of the initial dielectric layer 4033 is removed from the top of the initial dielectric layer along the Z-axis direction to expose a portion of the initial semiconductor body. In this case, the initial semiconductor body 4010 comprises an exposed initial semiconductor body 4011 and an unexposed initial semiconductor body 4012. The specific formation of removing portion of the initial dielectric layer may refer to the description in FIG. 5b.

Referring to FIG. 7c, a semiconductor thickening layer 7010 is formed on each side of the exposed initial semiconductor body 4011 by an epitaxial process. Here, the semiconductor thickening layer is formed uniformly based on each exposed surface of the exposed initial semiconductor body 4011. That is, the size of the semiconductor thickening layer along the Z-axis direction changes uniformly, and the size along the direction perpendicular to the Z-axis direction also changes uniformly. A shape of a cross section along a plane formed by the X-axis and the Y-axis of the exposed initial semiconductor body 4011 and the semiconductor thickening layer 7010 together is the same as a shape of a cross section along the plane of the exposed initial semiconductor body 4011. In some specific examples, materials of both the exposed initial semiconductor body 4011 and the semiconductor thickening layer 7010 comprise monocrystalline silicon. In some specific examples, a thickness (½ of the size along the X-axis direction) of the semiconductor thickening layer 7010 may be adjusted according to an actual process, for example, a thickness of the semiconductor thickening layer 7010 ranges from 1-5 nm.

In some specific examples, the semiconductor thickening layer 7010 may also be located on top of the exposed initial semiconductor body 4011 (not shown in FIG. 7c).

Referring to FIG. 7d, at least metallization process is performed on at least portion of the exposed initial semiconductor body 4011 and the semiconductor thickening layer 7010 to form a metal semiconductor compound layer 5010. In some examples, the metal elements in the metal semiconductor compound layer 5010 comprise, but are not limited to, nickel, cobalt, titanium, or the like.

In some specific examples, forming the metal semiconductor compound layer 5010 comprises: forming an initial metal layer covering the exposed surfaces (including the top surface of the exposed initial semiconductor body 4011 in FIG. 7c and each side surface of the semiconductor thickening layer 7010) of the to-be-metallized structure; and performing an annealing treatment on the to-be-metallized structure formed with the initial metal layer to form the metal semiconductor compound layer.

It should be noted that, in the metallization process, the metal semiconductor compound layer may have different proportions in the semiconductor material with different metallization levels. In some specific examples, in the metallization process, the exposed initial semiconductor body 4011 and the semiconductor thickening layer 7010 are all metalized together. Based on this, the formed conductive structure 1064 is all the metal semiconductor compound layer, and the unexposed initial semiconductor body 4012 forms the semiconductor body 1030, which may be specifically shown in FIG. 7d.

In some specific examples, in the metallization process, portions of the exposed initial semiconductor body 4011 and the semiconductor thickening layer 7010 are metallized, and the interior of the exposed initial semiconductor body 4011 is still the semiconductor layer 6010. Based on this, the formed conductive structure 1064 comprises a semiconductor layer 6010 and a metal semiconductor compound layer 5010 surrounding the semiconductor layer 6010, and the unexposed initial semiconductor body 4012 forms the semiconductor body 1030. It can be understood that since the semiconductor layer 6010 is actually a portion of the exposed initial semiconductor body 4011, the semiconductor layer 6010 is consistent with the entire initial semiconductor body, such as single crystal silicon, while there is no interface between the semiconductor layer 6010 and the unexposed initial semiconductor body 4012, which can be analogously understood with reference to FIG. 6b.

In some specific examples, during metallization process, the exposed initial semiconductor body 4011 and the semiconductor thickening layer 7010 are all metalized, while the metal semiconductor compound layer 5010 extends further into the unexposed initial semiconductor body 4012. It should be noted that in this case, the metal semiconductor compound extending into the unexposed initial semiconductor body 4012 may not have a regular shape, for example, the bottom of the middle is lower than the bottom of the edge. Based on this, there is a certain overlap between the formed conductive structure 1064 and the unexposed initial semiconductor body 4012. In this case, the formed conductive structure 1064 is all the metal semiconductor compound layer, and the portion of the unexposed initial semiconductor body 4012 which is not metallized forms the semiconductor body 1030, which may be analogously understood with reference to FIG. 6c.

It can be understood that in the foregoing example, a portion of the initial semiconductor body 4010 is thickened and metallized to form the conductive structure 1064, and another portion of the initial semiconductor 4010 is used to form the semiconductor body 1030. Because the initial semiconductor body 4010 is formed once from bottom to top, and the conductive structure 1064 and the semiconductor body 1030 share the same initial semiconductor body 4010, the conductive structure 1064 and the semiconductor body 1030 can be directly self-aligned, while the semiconductor thickening layer enables the structure which is metallized to be thicker, and a conductive structure with a larger size can be obtained, thereby improving the connection window between the conductive structure and the memory structure, and also achieving the effect of further reducing the contact resistance.

In some examples, referring to FIG. 7d, after the plurality of conductive structures 1064 are formed, the first dielectric layer 5020 is filled between the plurality of conductive structures 1064; the remaining of the initial dielectric layer forms the second dielectric layer 5030; and the first dielectric layer 5020 is the same as or different from the second dielectric layer 5030. In some specific examples, the first dielectric layer 5020 is the same as the second dielectric layer 5030, for example, both materials comprise silicon oxide. In some other specific examples, the first dielectric layer 5020 is different from the second dielectric layer 5030, for example, the first dielectric layer 5020 comprises silicon nitride or silicon boron nitride, and the second dielectric layer 5030 comprises silicon oxide.

In some examples, forming the semiconductor body and the conductive structure comprises:
Forming an initial semiconductor body extending along the first direction; the plurality of initial semiconductor bodies are separated by an initial dielectric layer; and exposing one of two surfaces of the initial semiconductor body opposite to each other along the first direction;
Performing a metallization process on a portion of the initial semiconductor body by using an exposed surface to form a metal semiconductor compound layer; and using the metal semiconductor compound layer as the conductive structure, and the remaining portion of the initial semiconductor body which is not metallized forms the semiconductor body.

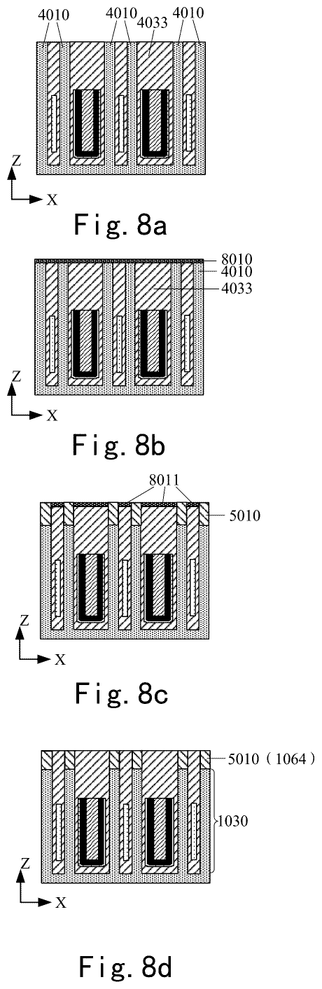

FIG. 8a to FIG. 8d are third schematic cross-sectional views of a process of forming a conductive structure and a semiconductor body according to an example of the present disclosure. In examples of the present disclosure, the upper end of the initial semiconductor body is metalized by directly using the exposed top surface of the initial semiconductor body. Specifically:

Referring to FIG. 8a, a plurality of initial semiconductor bodies 4010 extending along the Z-axis direction are formed; the plurality of initial semiconductor bodies 4010 are separated by an initial dielectric layer 4033. The specific formation of the initial semiconductor body 4010 may refer to the examples given in FIG. 4a to FIG. 4d.

Referring to FIG. 8b, an initial metal layer 8010 covering the top surface of the initial semiconductor body 4010 is formed. In this case, the initial metal layer 8010 covers the top surface of the initial semiconductor body 4010 and the top surface of the initial dielectric layer 4033, and the to-be-metallized structure formed with the initial metal layer is annealed. As previously mentioned, the metallization process is performed mainly in the semiconductor material covering the initial metal layer 8010.

Based on this, referring to FIG. 8c, a portion of the initial semiconductor body 4011 exposed at the top is subjected to a metallization process to form a metal semiconductor compound layer 5010. In some specific examples, the metal elements in the metal semiconductor compound layer 5010 comprise, but are not limited to, nickel, cobalt, titanium, or the like. The remaining metal layer 8011 covering the top surface of the initial dielectric layer 4033 remains. The metal semiconductor compound layer is used as the conductive structure 1064, and the remaining portion of the initial semiconductor body which is not metallized forms the semiconductor body 1030.

The metallization process is not performed in a non-semiconductor material, such as an oxide or nitride, that covers the initial metal layer. Based on this, referring to FIG. 8d, after forming the metal semiconductor compound layer, the remaining metal layer 8011 covering the non-semiconductor material is removed.

It can be understood that in the foregoing example, the conductive structure 1064 is formed by directly metallizing the exposed top of the initial semiconductor body 4010, and the semiconductor body 1030 is formed by using another portion of the initial semiconductor 4010. Because the initial semiconductor body 4010 is formed once from bottom to top, and the conductive structure 1064 and the semiconductor body 1030 share the same initial semiconductor body 4010, the conductive structure 1064 and the semiconductor body 1030 can be directly self-aligned, and meanwhile, compared with the solution shown in FIGS. 5a-5d, the process of removing the initial dielectric layer is further reduced, the scheme is simple, and the manufacturing process is further saved.

It should be noted that the first dielectric layer between the plurality of conductive structures is the same as the second dielectric layer between the plurality of semiconductor bodies. In some specific examples, both the first dielectric layer and the second dielectric layer comprise silicon oxide. As stated previously, if the insulating material used in the subsequent process of forming the memory structure comprises silicon oxide, before forming the memory structure, a barrier layer whose etch selectivity ratio is different from the etch selectivity ratio of silicon oxide needs to be formed on the second dielectric layer.

It should be noted that, in the foregoing several examples, since the conductive structure and the semiconductor body used to form the vertical crystal transistor share the same semiconductor pillar, no matter whether the source and the drain of the vertical crystal transistor are doped before or after metallization, doping ions are left in the conductive structure. Based on this, the semiconductor body extends along a first direction; the conductive structure has a doping ion, and a type of the doping ion is the same as a doping type of a doping ion in two ends of the semiconductor body opposite to each other along the first direction.

In some examples, forming the semiconductor pillar semiconductor body and the interconnection structure conductive structure comprises:
Forming a plurality of initial semiconductor bodies extending along the first direction, the plurality of initial semiconductor bodies are separated by an initial dielectric layer;
Removing a portion of the initial semiconductor body to form a second trench in the initial dielectric layer; the remaining of the initial semiconductor body forming the semiconductor body;
Widening the second trench to form a first trench; a size of the first trench along a second direction is greater than a size of the second trench along the second direction, and the second direction is perpendicular to the first direction;
Forming the conductive structure in the first trench.

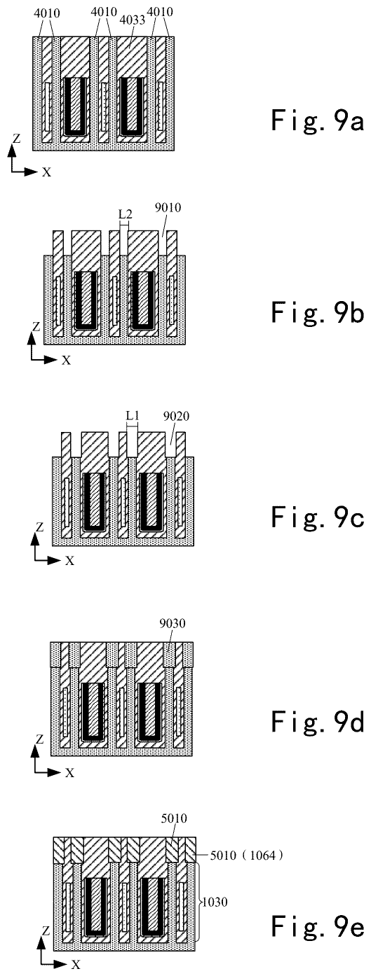

FIG. 9a to FIG. 9e are fourth schematic cross-sectional views of a process of forming a conductive structure and a semiconductor body according to an example of the present disclosure. In the examples of the present disclosure, after the upper end of the initial semiconductor body is removed, the removed position is widened, and the semiconductor material formed in the widened position is metalized. Specifically:

Referring to FIG. 9a, a plurality of initial semiconductor bodies 4010 extending along the Z-axis direction are formed; the plurality of initial semiconductor bodies 4010 are separated by an initial dielectric layer 4033. The specific formation of the initial semiconductor body 4010 may refer to the examples given in FIG. 4a to FIG. 4d.

Referring to FIG. 9b, a portion of the initial semiconductor body 4010 is removed from the top of the initial dielectric layer along the Z-axis direction, and a second trench 9010 is formed in the initial dielectric layer 4033. In some examples, after the portion of the initial semiconductor body 4010 is removed, a top surface of the remaining of the initial semiconductor body is higher than a top surface of the gate electrode, and the remaining initial semiconductor body forms the semiconductor body. In some specific examples, the method for forming the second trench 9010 may comprise, but is not limited to, dry etching.

It may be understood that, after the portion of the initial semiconductor body 4010 is removed, a size of the second trench 9010 along the second direction (that is, the X-axis direction) is the same as a size of the initial semiconductor body 4010 along the second direction (that is, the X-axis direction), and a size of the second trench 9010 along the third direction (that is, the Y-axis direction) is the same as a size of the initial semiconductor body 4010 along the third direction (that is, the Y-axis direction).

In some examples, referring to FIG. 9c, a portion of the initial dielectric layer 4033 on the side surface of the second trench 9010 is removed, and the second trench 9010 is widened to form the first trench 9020. In some specific examples, the method for removing the portion of the initial dielectric layer 4033 on the side surface of the second trench 9010 may comprise, but is not limited to, dry etching.

It may be understood that a size L1 of the first trench 9020 obtained after the second trench 9010 is widened along the second direction (that is, the X-axis direction) is greater than a size L2 of the second trench 9010 along the second direction (that is, the X-axis direction); and/or a size of the first trench 9020 along the third direction (that is, the Y-axis direction) is greater than a size of the second trench 9010 along the third direction (that is, the Y-axis direction).

Referring to FIG. 9d, the conductive structure 1064 is formed in the first trench 9020. In some examples, forming the conductive structure in the first trench 9020 may comprise: firstly forming the initial semiconductor layer 9030 in the first trench 9020. In some specific examples, the initial semiconductor layer 9030 is formed in the first trench 9020 by a deposition process, and the initial semiconductor layer comprises a polycrystalline material, such as polysilicon. In some other specific examples, the initial semiconductor layer 9030 is formed in the first trench 9020 by an epitaxial process, and the initial semiconductor layer comprises a monocrystalline material, such as monocrystalline silicon.

Referring to FIG. 9e, the initial semiconductor layer 9030 is metalized to form a metal semiconductor compound layer 5010, and the metal semiconductor compound layer 5010 is used as the conductive structure 1064. For a specific metallization process, reference may be made to the foregoing metallization process for understanding.

It should be noted that, in the examples of the present disclosure, the second trench 9010 may not be widened, and the semiconductor compound layer 5010 may be directly formed in the second trench 9010, to obtain the conductive structure 1064.

In some examples, forming the semiconductor body and the conductive structure comprises:
Forming a plurality of initial semiconductor bodies extending along the first direction, wherein the plurality of initial semiconductor bodies are separated by an initial dielectric layer;
Removing a portion of the initial dielectric layer along the first direction to expose a portion of the initial semiconductor body;
Forming liner layers covering an exposed side surface of the initial semiconductor body;
Filling a first dielectric layer between the liner layers;
Removing a portion of the initial semiconductor body, wherein the remaining initial semiconductor body forms the semiconductor body, and the remaining initial dielectric layer forms the second dielectric layer;
Removing a portion of the liner layer covering a side surface of the first dielectric layer to form a plurality of first trenches, wherein the remaining of the liner layer forms a third dielectric layer; and
Forming the conductive structure in the first trench.

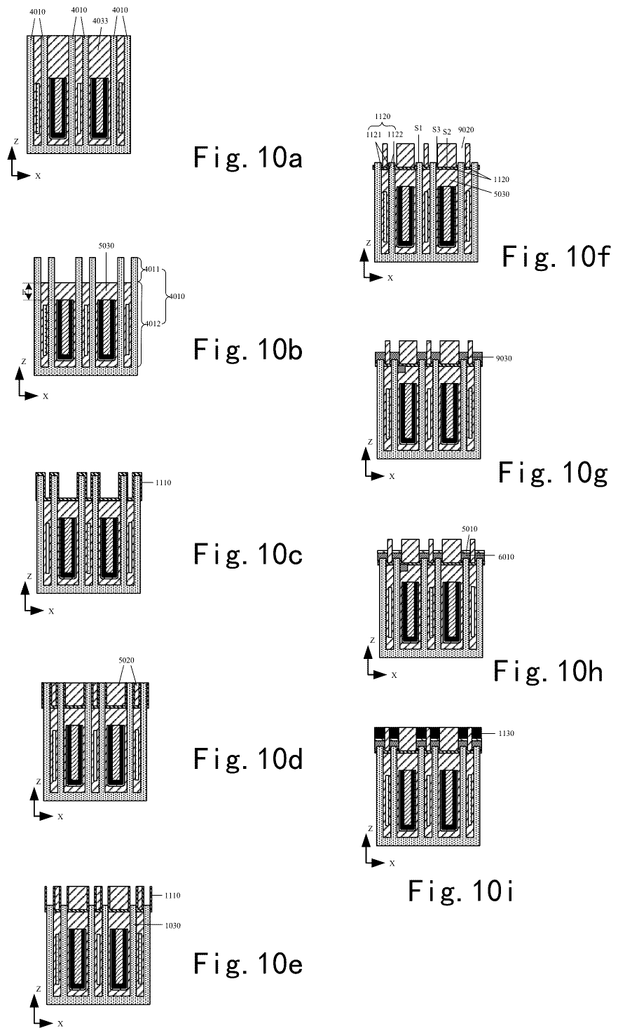

FIG. 10a to FIG. 10i are fifth schematic cross-sectional views of a process of forming a conductive structure and a semiconductor body according to an example of the present disclosure. In the examples of the present disclosure, a semiconductor material with a larger size than that of the initial semiconductor body is subsequently formed by forming a liner layer on the periphery of the exposed upper end of the initial semiconductor body, and the semiconductor material is metalized. Specifically:

Referring to FIG. 10a, a plurality of initial semiconductor bodies 4010 extending along the Z-axis direction are formed; the plurality of initial semiconductor bodies 4010 are separated by an initial dielectric layer 4033. The specific formation of the initial semiconductor body 4010 may refer to the examples given in FIG. 4a to FIG. 4d.

Referring to FIG. 10b, a portion of the initial dielectric layer 4033 is removed from the top of the initial dielectric layer 4033 along the Z-axis direction to expose a portion of the initial semiconductor body. In this case, the initial semiconductor body 4010 comprises an exposed initial semiconductor body 4011 and an unexposed initial semiconductor body 4012. The remaining of the initial dielectric layer forms the second dielectric layer 5030, wherein the specific formation of removing the portion of the initial dielectric layer may refer to the description in FIG. 5b.

Referring to FIG. 10c, a liner layer 1110 is formed on both a top surface and a side surface of the exposed initial semiconductor body 4011. Here, the liner layer 1110 is uniformly formed based on each exposed surfaces of the exposed initial semiconductor body 4011, that is, the size of the liner layer along the Z-axis direction changes uniformly, and the size along the direction perpendicular to the Z-axis direction also changes uniformly. A shape of a cross section along a plane formed by the X-axis and the Y-axis of the exposed initial semiconductor body 4011 and liner layer 1110 together is the same as a shape of a cross section along the plane of the exposed initial semiconductor body 4011. In some specific examples, the method of forming the liner layer 1110 comprises, but is not limited to, PVD, CVD, ALD, or the like. In some specific examples, a thickness (½ of the size along the X-axis direction) of the liner layer 1110 may be adjusted according to an actual process, for example, a thickness of the liner layer 1110 ranges from 1-5 nm.

Referring to FIG. 10d, a first dielectric layer 5020 is filled between the liner layers 1110. In some examples, the etching selectivity ratios of the liner layer 1110 and the first dielectric layer are different. For example, the first dielectric layer 5020 may comprise an oxide, such as silicon oxide; and the liner layer 1110 may comprise a nitride, such as one or more of silicon nitride, silicon oxynitride, or a high dielectric material. In some specific examples, the method of forming the first dielectric layer 5020 comprises depositing a first dielectric material layer between the liner layers 1110 by a process such as PVD, CVD, or the like, removing a portion of the first dielectric material layer by a process such as CMP, or the like, wherein the portion of the liner layer 1110 at the top of the exposed initial semiconductor body 4011 is removed while the portion of the first dielectric material layer is removed, to expose the top of the initial semiconductor body 4011.

Referring to FIG. 10e, a portion of the initial semiconductor body is removed from the top of the exposed initial semiconductor body 4011 along the Z-axis direction, and a surface S1 of the remaining initial semiconductor body is higher than a surface of the liner layer 1110 perpendicular to the first direction. The remaining initial semiconductor body forms the semiconductor body 1030. In some specific examples, the method of removing portion of the initial semiconductor body 4011 comprises, but is not limited to, a dry etching process.

Referring to FIG. 10f, a portion of the liner layer 1110 covering the side surface of the first dielectric layer 5020 is removed to form a plurality of first trenches 9020, the remaining liner layer 1110 forms the third dielectric layer 1120, and a surface S1 of the remaining initial semiconductor body is higher than a surface S2 of the third dielectric layer close to the first dielectric layer. In some specific examples, the method of removing the portion of the liner layer 1110 covering the side surface of the first dielectric layer 5020 comprises, but is not limited to, a wet etching process.

In some examples, the third dielectric layer 1120 may comprise at least a first sub-dielectric layer, and the third dielectric layer 1120 may comprise a first sub-dielectric layer 1121 and a second sub-dielectric layer 1122, wherein the first sub-dielectric layer 1121 extends along the second direction (that is, the X-axis direction) and covers the second dielectric layer 5030, and the second sub-dielectric layer 1122 extends along the first direction (that is, the Z-axis direction) and covers a portion of the side surface of the initial semiconductor body 4010.

In some examples, one of two ends of the remaining semiconductor body opposite to each other along the first direction, which is close to the first trench 9020 extends into the first trench 9020; a surface S1 of the remaining of the initial semiconductor body close to the first trench 9020 is higher than a surface S3 of the second sub-dielectric layer 1122 close to the first trench 9020.

In some examples, a sum of a size of the second sub-dielectric layer 1122 and a size of the remaining initial semiconductor body in the second direction (that is, the Y-axis direction) is the same as a size of the first trench 9020 in the second direction (that is, the Y-axis direction).

It may be understood that a size of the first trench 9020 along the second direction (that is, the X-axis direction) is greater than a size of the initial semiconductor body 4010 along the second direction (that is, the X-axis direction) while a size of the first trench 9020 along the third direction, that is (the Y-axis direction) is greater than a size of the initial semiconductor body 4010 along the third direction (that is, the Y-axis direction). That is, the removal of the liner layer is subsequently used to form the conductive structure with a size greater than that of the initial semiconductor body, so that the effect of thickening the conductive structure is achieved, and the thickness of the liner layer is the thickness of the conductive structure that is thickened compared with the initial semiconductor body 4010.

In addition, due to the large area of the second dielectric layer 5030, there may be defects during filling, such as cavities. Here, S1 is higher than S2, so that the second layer 5030 is protected from being exposed, thereby avoiding adverse consequences caused by the etching solution entering the cavity when the portion of the liner layer 1110 on the side surface of the first dielectric layer 5020 is removed by wet etching.

Next, referring to FIG. 10g, FIG. 10h and FIG. 10i, the conductive structure 1064 is formed in the first trench 9020. In some examples, forming the conductive structure in the first trench comprises: forming an initial semiconductor layer 9030 in the first trench; and performing a metallization process on the initial semiconductor layer 9030 to form the metal semiconductor compound layer 5010.

In some specific examples, referring to FIG. 10g, forming the initial semiconductor layer in the first trench comprises: forming the initial semiconductor layer 9030 in the first trench 9020 by a deposition process, where the initial semiconductor layer 9030 comprises a polycrystalline material, such as polysilicon.

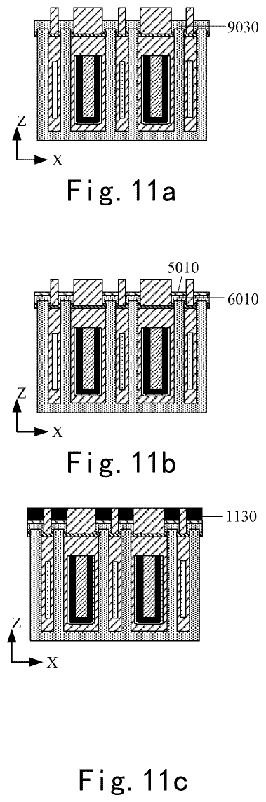

FIG. 10a to FIG. 10f and FIG. 11a, FIG. 11b and FIG. 11c are sixth schematic cross-sectional views of a process of forming a conductive structure and a semiconductor body according to an example of the present disclosure. That is, FIG. 11g is a schematic diagram of the continuation of FIG. 10f.

In some specific examples, referring to FIG. 11a, forming an initial semiconductor layer in the first trench comprises: forming the initial semiconductor layer 9030 in the first trench 9020 by an epitaxial process, where the initial semiconductor layer 9030 comprises a monocrystalline material, such as monocrystalline silicon.

Next, referring to FIG. 10h and FIG. 11b, the initial semiconductor layer 9030 is metallized to form a metal semiconductor compound layer 5010, an initial semiconductor layer 9030 which is not metallized forms a semiconductor layer 6010.

It should be noted that here, the metal semiconductor compound layer 5010 extends along the second direction or the third direction. In other words, the plane of the metal semiconductor compound layer 5010 is perpendicular to the first direction. In some specific examples, the metal elements in the metal compound layer comprise, but are not limited to, nickel, cobalt, or titanium. For a specific metallization process, reference may be made to the foregoing metallization process for understanding. Here, the semiconductor layer 6010 is in contact with the semiconductor body 1030 and is located on a side of the metal semiconductor compound layer 5010 close to the semiconductor body 1030.

Next, in some examples, referring to FIG. 10i and FIG. 11c, a metal layer 1130 may be further formed on the metal semiconductor compound layer 5010, and the metal layer 1130 is located on a side of the metal semiconductor compound layer away from the semiconductor layer 6010. In some specific examples, the metal layer 1130 comprises, but is not limited to, tungsten or copper.

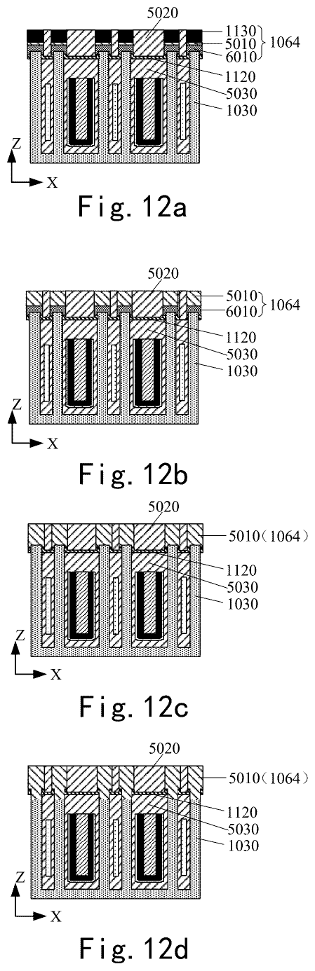

It should be noted that, in the metallization process, with different metallization levels, the metal semiconductor compound layer may have different proportions in the initial semiconductor, and in addition, the metal layer may be selectively added. FIG. 12a to FIG. 12d are second schematic cross-sectional views of different proportions of a metal semiconductor compound layer in a semiconductor material in several metallization processes according to some examples of the present disclosure.

In some specific examples, as shown in FIG. 12a, in the metallization process, a portion of the initial semiconductor layer 9030 is metalized, the top of the initial semiconductor layer 9030 is metalized, the rest of the initial semiconductor layer 9030 is not metalized, while the top of the initial semiconductor layer 9030 is further formed with the metal layer 1130. Based on this, the formed conductive structure 1064 comprises a semiconductor layer 6010, a metal semiconductor compound layer 5010, and a metal layer 1130 stacked in sequence.

In some specific examples, as shown in FIG. 12b, in the metallization process, a portion of the initial semiconductor layer 9030 is metalized, the top of the initial semiconductor layer 9030 is metalized, the rest of the initial semiconductor layer 9030 is not metalized, while the top of the initial semiconductor layer 9030 no longer forms the metal layer. Based on this, the formed conductive structure 1064 comprises a semiconductor layer 6010 and a metal semiconductor compound layer 5010 stacked in sequence.

In some specific examples, as shown in FIG. 12c, in the metallization process, the initial semiconductor layer 9030 is all metalized while the top of the initial semiconductor layer 9030 no longer forms a metal layer. Based on this, the formed conductive structure 1064 is all the metal semiconductor compound layer.

In some specific examples, as shown in FIG. 12d, in the metallization process, the initial semiconductor layer 9030 is all metalized while the metal semiconductor compound layer 5010 further extends into the initial semiconductor body 4010 below the third dielectric layer, while the top of the initial semiconductor layer 9030 no longer forms a metal layer. Based on this, there is a certain overlap between the formed conductive structure 1064 and the initial semiconductor body 4010 below the third dielectric layer. In this case, the formed conductive structure 1064 is all the metal semiconductor compound layer, and the portion of the initial semiconductor body 4010 below the third dielectric layer which is not metalized forms the semiconductor body 1030.

It can be understood that in the foregoing example, a portion of the initial semiconductor body 4010 which is thickened and metallized is used to form the conductive structure 1064, and another portion of the initial semiconductor 4010 is used to form the semiconductor body 1030. Because the initial semiconductor body 4010 is formed once from bottom to top, and the conductive structure 1064 and the semiconductor body 1030 share the same initial semiconductor body 4010, the conductive structure 1064 and the semiconductor body 1030 can be directly self-aligned, while the initial semiconductor body 4010 can be thickened by the liner layer to obtain a conductive structure with a larger size, thereby improving the connection window between the conductive structure and the memory structure, and further reducing the contact resistance.

Meanwhile, by thickening the initial semiconductor body 4010 by the liner layer, the liner layer can be conformally formed on the surface of the initial semiconductor body, and the process controllability is better; in addition, thickening the initial semiconductor body 4010 by the liner layer does not need to provide an additional mask layer, so that the manufacturing cost is reduced.

The fabrication of the conductive structure and the semiconductor body is completed here, and the fabrication of other structures of the semiconductor device is described next.

Next, a memory structure is formed on one of two sides of the conductive structure along the first direction, which is away from the surface of the semiconductor body; the method for forming the memory structure is well known, and details are not described herein again.

In some specific examples, the memory structure comprises a capacitor; forming the memory structure comprises forming a cup-shaped capacitor CUP, a cylinder-shaped capacitor CYL, or a pillar-shaped capacitor PIL. The shape of the capacitor may be selected according to actual requirements, which is not limited in the present disclosure.

In some examples, the method further comprises: forming a word line on at least one side of the semiconductor body; and forming a bit line on one of two surfaces of the semiconductor body opposite to each other along the first direction, which is away from the conductive structure.

Here, the word line may extend along a third direction, and the bit line may extend along a second direction.

In some examples, forming the word line on at least one side of the semiconductor body comprises: forming the word line on one side surface of the semiconductor body; forming the word line on two side surfaces opposite to each other of the semiconductor body; and forming the word line surrounding a side surface of the semiconductor body.

It may be understood that the conductive structures in the examples of the present disclosure may be applied to different word line (gate structures) scenarios. For example, the conductive structure in the examples of the present disclosure may be applied to a scenario in which two word line structures corresponding to two adjacent semiconductor bodies are disposed back-to-back, respectively. The accompanying drawings in the examples of the present disclosure take a scenario with back-to-back configuration as an example.

In some specific examples, two adjacent ones of the semiconductor bodies form a semiconductor body group, and two semiconductor bodies in one semiconductor body group are separated by a first isolation structure (that is, the first isolation structure 4020 in FIG. 4d); two adjacent semiconductor body groups are separated by a second isolation structure (that is, a final form corresponding to the second isolation structure 4030 in FIG. 4d, and a lower end of the gate electrode is disconnected); forming a word line on at least one side of the semiconductor body comprises: forming the word line on one of two side surfaces of a respective semiconductor body in the semiconductor body group away from the first isolation structure, respectively.

According to the examples of the present disclosure, by the ingenious utilization of the initial semiconductor body, the self-alignment of the conductive structure and the semiconductor body can be achieved, so that the alignment precision of the semiconductor body of the conductive structure can be increased, the alignment difficulty of the semiconductor body and the semiconductor body is reduced, the reliability of the semiconductor device is improved, the manufacturing time and the cost are saved, and the process speed and efficiency are improved; and on the other hand, the metal semiconductor compound layer is used as the conductive structure between the semiconductor body and the memory structure, the resistivity is low, better electrical connection between the semiconductor body and the memory structure can be achieved, and the reliability of the semiconductor device is improved.

The examples of the present disclosure further provides a semiconductor device, comprising: a plurality of conductive structures; a plurality of semiconductor bodies located on a side of the conductive structures in a first direction and connected to the conductive structures; a first dielectric layer located between the plurality of conductive structures; a second dielectric layer located between the plurality of semiconductor bodies; and a third dielectric layer located between the first dielectric layer and the second dielectric layer.

In some examples, a size of a cross section of the conductive structure perpendicular to the first direction is greater than a size of a cross section of the semiconductor body perpendicular to the first direction.

In some examples, the conductive structure and the semiconductor body form a step structure at a joint of the conductive structure and the semiconductor body, and the step structure comprises a side surface extending along the first direction and a step surface extending along a second direction.

In some examples, sizes of the step structure along the second direction are the same in the first direction, and sizes of the step structure along the first direction are the same in the second direction.

In some examples, the conductive structure comprises at least a metal semiconductor compound layer.

In some examples, a metal element in the metal compound layer comprises nickel, cobalt, or titanium.

In some examples, the conductive structure further comprises a semiconductor layer in contact with the semiconductor body and located on a side of the metal semiconductor compound layer close to the semiconductor body.

In some examples, the semiconductor layer comprises a monocrystalline material or a polycrystalline material.

In some examples, the conductive structure further comprises a metal layer located on a side of the metal semiconductor compound layer away from the semiconductor layer.

In some examples, the metal layer comprises tungsten or copper.

In some examples, etching selectivity ratios of the third dielectric layer and the first dielectric layer are different.

In some examples, the first dielectric layer comprises an oxide, and the third dielectric layer comprises a nitride.

In some examples, the third dielectric layer comprises a first sub-dielectric layer and a second sub-dielectric layer; the first sub-dielectric layer extends along a second direction and covers the second dielectric layer, the second sub-dielectric layer extends along a first direction and covers a side surface of the semiconductor body; and the second direction is perpendicular to the first direction.

In some examples, one of two ends of the semiconductor body opposite to each other along the first direction extends into the conductive structure; and a surface of the semiconductor body close to the conductive structure is higher than a surface of the second sub-dielectric layer close to the conductive structure.

In some examples, a sum of sizes of the second sub-dielectric layer and the semiconductor body in the second direction is the same as a size of the conductive structure in the second direction.

In some examples, the plurality of semiconductor bodies are arranged in an array; the semiconductor device further comprises: a plurality of memory structures, wherein each of the memory structures is located on one of two sides of the conductive structure along the first direction, which is away from the semiconductor body, and is connected to the conductive structure; a plurality of word lines, wherein the word line is coupled to at least one side surface of each of a row of the semiconductor bodies; and a plurality of bit lines, wherein the bit line is coupled to one of two surfaces of each of a column of the semiconductor bodies opposite to each other along the first direction, which is away from the conductive structure.

In some examples, the word line is located on one side surface of the semiconductor body; or the word line is located on two side surfaces opposite to each other of the semiconductor body; or the word line surrounds a side surface of the semiconductor body.

In some examples, two adjacent ones of the semiconductor bodies form a semiconductor body group, and the two semiconductor bodies in one semiconductor body group are separated by a first isolation structure; two adjacent semiconductor body groups are separated by a second isolation structure; and the two word of the lines are respectively located on one of two side surfaces of a respective semiconductor body in the semiconductor body group away from the first isolation structure.

In some examples, the memory structure comprises a capacitor; the capacitor comprises a cup-shaped capacitor, a cylinder-shaped capacitor, or a pillar-shaped capacitor.

It should be noted that the features of the structures in the above semiconductor device may be understood with reference to the features of the structures described in the manufacturing method of the semiconductor device.

In some examples, the semiconductor device comprises a memory device comprising DRAM.

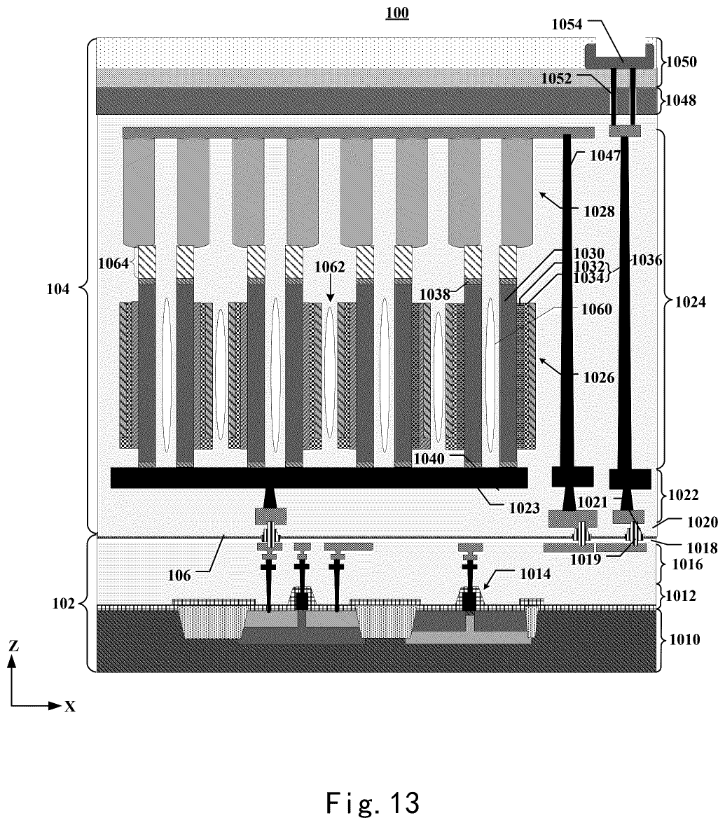

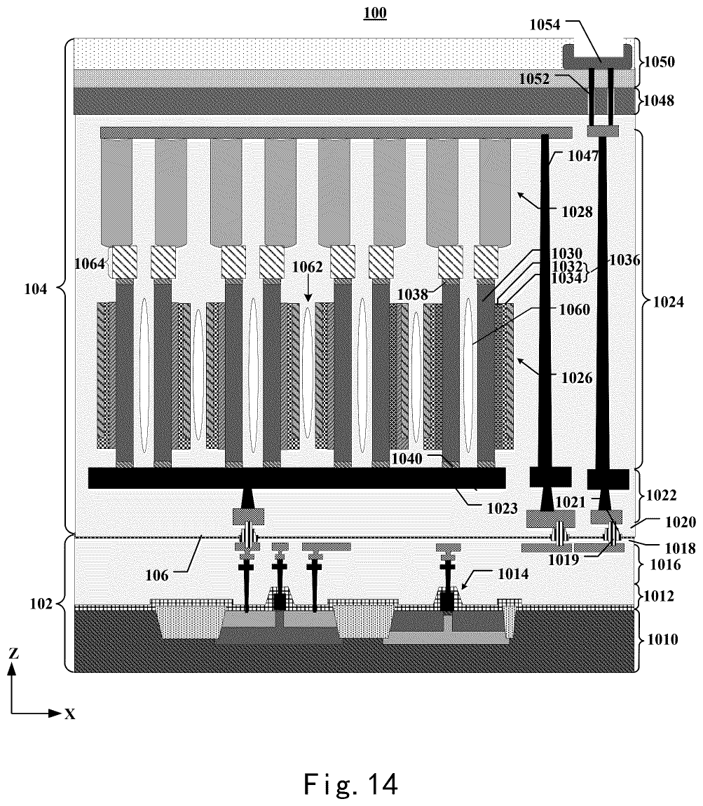

FIG. 13 is a second schematic structural diagram of a dynamic random access memory according to an example of the present disclosure; as shown in FIG. 13, the semiconductor device 100 comprises: a plurality of conductive structures 1064; a plurality of semiconductor bodies 1030, where the semiconductor body 1030 is located on a side of the conductive structure 1064 along a first direction (for example, a Z-axis), and is connected to the conductive structure 1064; a first dielectric layer 5020 located between the plurality of conductive structures 1064; a second dielectric layer 5030 located between the plurality of semiconductor bodies 1030; and a third dielectric layer 1120 located between the first dielectric layer 5020 and the second dielectric layer 5030. The conductive structure 1064 is aligned with the geometric center of the semiconductor body 1030, and it should be understood that the alignment herein needs to eliminate the fine deviation caused by manufacturing errors and the like. A size of the conductive structure 1064 along the second direction (e.g., the X-axis) is greater than the size of the semiconductor body 1030 along the second direction (e.g., the X-axis), and the sizes of the two sides of the conductive structure 1064 with respect to the semiconductor body 1030 are the same. The conductive structure 1064 comprises a semiconductor layer, a metal semiconductor body compound layer, and a metal layer sequentially stacked along the first direction. In addition, the third dielectric layer 1120 can be clearly distinguished from the first dielectric layer 5020 and the second dielectric layer 5030. Other structures shown in FIG. 13 may be understood with reference to FIG. 1. FIG. 14 is a third schematic structural diagram of a dynamic random access memory according to an example of the present disclosure; the difference from FIG. 13 is that the conductive structure 1064 comprises a semiconductor layer and a metal semiconductor body compound layer that are sequentially stacked along a first direction.

It should be noted that FIG. 13 and FIG. 14 show only an application example of the conductive structure and the semiconductor body in the dynamic random access memory in the foregoing examples of the present disclosure, and it may be understood that other conductive structures and semiconductor bodies in the foregoing examples of the present disclosure may also be applied to the dynamic random access memory.

It should be noted that similar to FIG. 1, FIG. 13 and FIG. 14 show only an example in which the first device 102 and the second device 104 are connected in a bonding manner, and it may be understood that other conductive structures and semiconductor bodies in the foregoing examples of the present disclosure may also be applied to cases where the foregoing first device 102 and the second device 104 are directly formed on a same substrate.

It should be noted that similar to FIG. 1, FIG. 13 and FIG. 14 show only an example in which two gate structures corresponding to two adjacent semiconductor bodies are disposed back-to-back, respectively, and it may be understood that other conductive structures and semiconductor bodies in the foregoing examples of the present disclosure may also be applied to various different cases where the foregoing gate structures on a same side of the semiconductor body, the gate structures are located on opposite sides of the semiconductor body, and the gate structures surround the semiconductor body.

Examples of the present disclosure further provides a memory system, comprising: the semiconductor device according to the above examples of the present disclosure; and a memory controller connected to the semiconductor device and configured to control the semiconductor device.

It should be noted that, the technical solutions described in the examples of the present disclosure may be arbitrarily combined in the case of no conflict.

In the examples of the present disclosure, the protection scope of the present disclosure is not limited thereto, and any person skilled in the art may easily conceive variations or replacements within the technical scope of the present disclosure, which should be covered within the protection scope of the present disclosure. Therefore, the protection scope of the present disclosure should be defined by the protection scope of the claims.

What is claimed is:

1. A semiconductor device, comprising:
a plurality of conductive structures;
a plurality of semiconductor bodies located on a side of the plurality of conductive structures in a first direction and connected to the plurality of conductive structures;
a first dielectric layer located between the plurality of conductive structures;
a second dielectric layer located between the plurality of semiconductor bodies; and
a third dielectric layer located between the first dielectric layer and the second dielectric layer.

2. The semiconductor device of claim 1, wherein a size of a cross section of a conductive structure perpendicular to the first direction is greater than a size of a cross section of a semiconductor body perpendicular to the first direction.

3. The semiconductor device of claim 2, wherein the conductive structure and the semiconductor body form a step structure at a joint of the conductive structure and the semiconductor body, and the step structure comprises a side surface extending along the first direction and a step surface extending along a second direction.

4. The semiconductor device of claim 3, wherein sizes of the step structure along the second direction are the same in the first direction, and sizes of the step structure along the first direction are the same in the second direction.

5. The semiconductor device of claim 1, wherein each of the plurality of conductive structures comprises at least a metal semiconductor compound layer.

6. The semiconductor device of claim 5, wherein the conductive structure further comprises a semiconductor layer in contact with a semiconductor body and located on a side of the metal semiconductor compound layer close to the semiconductor body.

7. The semiconductor device of claim 6, wherein the semiconductor layer comprises a monocrystalline material or a polycrystalline material.

8. The semiconductor device of claim 6, wherein the conductive structure further comprises a metal layer located on a side of the metal semiconductor compound layer away from the semiconductor layer.

9. The semiconductor device of claim 1, wherein etching selectivity ratios of the third dielectric layer and the first dielectric layer are different.

10. The semiconductor device of claim 1, wherein the third dielectric layer comprises a first sub-dielectric layer and a second sub-dielectric layer; the first sub-dielectric layer extends along a second direction and covers the second dielectric layer, and the second sub-dielectric layer extends along the first direction and covers a side surface of a semiconductor body; and the second direction is perpendicular to the first direction.

11. The semiconductor device of claim 10, wherein one of two ends of the semiconductor body opposite to each other along the first direction extends into at least one conductive structure of the plurality of conductive structures; and a surface of the semiconductor body close to the at least one conductive structure is higher than a surface of the second sub-dielectric layer close to the at least one conductive structure.

12. The semiconductor device of claim 11, wherein a sum of sizes of the second sub-dielectric layer and the semiconductor body in the second direction is the same as a size of the conductive structure in the second direction.

13. The semiconductor device of claim 1, wherein the plurality of semiconductor bodies are arranged in an array; and
the semiconductor device further comprises:
a plurality of memory structures, wherein each of the plurality of memory structures is located on one of two sides of at least one conductive structure of the plurality of conductive structures along the first direction that is away from a semiconductor body, and is connected to the at least one conductive structure;
a plurality of word lines, wherein each of the plurality of word lines is coupled to at least one side surface of each of a row of the semiconductor bodies; and
a plurality of bit lines, wherein each of the plurality of bit lines is coupled to one of two surfaces disposed of each of a column of the semiconductor bodies opposite to each other along the first direction, which is away from the at least one conductive structure.

14. A manufacturing method of a semiconductor device, comprising:
forming a plurality of conductive structures;
forming a plurality of semiconductor bodies, wherein the semiconductor bodies are located on a side of the plurality of conductive structures along a first direction and are connected to the plurality of conductive structures;
forming a first dielectric layer, wherein the first dielectric layer is located between the plurality of conductive structures;
forming a second dielectric layer, wherein the second dielectric layer is located between the plurality of semiconductor bodies; and
forming a third dielectric layer, wherein the third dielectric layer is located between the first dielectric layer and the second dielectric layer.

15. The manufacturing method of the semiconductor device of claim 14, wherein forming the semiconductor bodies and the plurality of conductive structures comprises:
forming a plurality of initial semiconductor bodies extending along the first direction, wherein the plurality of initial semiconductor bodies are separated by an initial dielectric layer;
removing a portion of the initial dielectric layer along the first direction to expose a portion of the initial semiconductor body, wherein remaining initial dielectric layer forms the second dielectric layer;
forming a liner layer covering an exposed side surface of the initial semiconductor body;
filling a first dielectric layer between the liner layers;
removing a portion of the initial semiconductor body, wherein remaining initial semiconductor body forms a semiconductor body;
removing a portion of the liner layer covering a side surface of the first dielectric layer to form a plurality of first trenches, wherein remaining liner layer forms the third dielectric layer; and
forming a conductive structure in the first trench.

16. The manufacturing method of the semiconductor device of claim 15, wherein forming the conductive structure in the first trench comprises:
forming an initial semiconductor layer in the first trench;
performing a metallization process on the initial semiconductor layer to form a metal semiconductor compound layer.

17. The manufacturing method of the semiconductor device of claim 16, wherein the forming the initial semiconductor layer in the first trench comprises:
forming the initial semiconductor layer in the first trench by a deposition process, wherein the initial semiconductor layer comprises a polycrystalline material.

18. The manufacturing method of the semiconductor device of claim 16, wherein the forming the initial semiconductor layer in the first trench comprises:
forming the initial semiconductor layer in the first trench by an epitaxial process, wherein the initial semiconductor layer comprises a monocrystalline material.

19. The manufacturing method of the semiconductor device of claim 16, further comprising:
forming a metal layer on the metal semiconductor compound layer.

20. The manufacturing method of the semiconductor device of claim 14, further comprising
forming a memory structure on one of two sides of the conductive structure along the first direction, which is away from the semiconductor body;
forming a word line on at least one side of the semiconductor body; and
forming a bit line on one of two surfaces of the semiconductor body opposite to each other along the first direction, which is away from the conductive structure.
